(19) United States
(12) Patent Application Publication
(10) Pub. No.: US 2022/0083252 A1
(43) Pub. Date: Mar. 17, 2022

(54) INDICATION-BASED AVOIDANCE OF DEFECTIVE MEMORY CELLS

(71) Applicant: Micron Technology, Inc., Boise, ID (US)

(72) Inventors: Justin Eno, El Dorado Hills, CA (US); Sean S. Eilert, Penryn, CA (US)

(21) Appl. No.: 17/019,843

(22) Filed: Sep. 14, 2020

(51) Int. Cl. G06F 3/06

(52) U.S. Cl. CPC G06F 3/0653; G06F 3/0655; G06F 3/0679; G06F 3/0619

(57) ABSTRACT

Methods, systems, and devices for indication-based avoidance of defective memory cells are described. A non-volatile memory component may store information regarding one or more memory cells of a volatile memory component that a host device for the volatile memory component is to avoid accessing. The one or more memory cells may be defective for example. The device may transmit, to the non-volatile memory component, a request for an indication of the one or more memory cells of the volatile memory component that the host device is to avoid accessing, and the non-volatile memory may transmit such an indication to the host device. The host device may refrain from writing or reading from the one or more memory cells of the volatile memory component.

### BACKGROUND

The following relates generally to one or more systems for memory and more specifically to indication-based avoidance of defective memory cells.

Memory devices are widely used to store information in various electronic devices such as computers, wireless communication devices, cameras, digital displays, and the like. Information is stored by programing memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read, or sense, at least one stored state in the memory device. To store information, a component may write, or program, the state in the memory device.

Various types of memory devices and memory cells exist, including magnetic hard disks, random access memory (RAM), read-only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), self-selecting memory, chalcogenide memory technologies, and others. Memory cells may be volatile or non-volatile. Non-volatile memory, e.g., FeRAM, may maintain their stored logic state for extended periods of time even in the absence of an external power source. Volatile memory devices, e.g., DRAM, may lose their stored state when disconnected from an external power source.

### BRIEF DESCRIPTION OF THE DRAWINGS

FIG. 1 illustrates an example of a system that supports indication-based avoidance of defective memory cells in accordance with examples as disclosed herein.

FIG. 2 illustrates an example of an address indication scheme that supports indication-based avoidance of defective memory cells in accordance with examples as disclosed herein.

FIG. 3 illustrates an example of a device communication configuration that supports indication-based avoidance of defective memory cells in accordance with examples as disclosed herein.

FIG. 4 illustrates an example of a device communication configuration that supports indication-based avoidance of defective memory cells in accordance with examples as disclosed herein.

FIG. 5 shows a block diagram of a host device that supports indication-based avoidance of defective memory cells in accordance with examples as disclosed herein.

FIG. 6 shows a block diagram of a memory device that supports indication-based avoidance of defective memory cells in accordance with examples as disclosed herein.

FIGS. 7 and 8 show flowcharts illustrating a method or methods that support indication-based avoidance of defective memory cells in accordance with examples as disclosed herein.

### DETAILED DESCRIPTION

A system (e.g., a host device coupled with a memory device or set of memory devices) may include volatile memory (e.g., dynamic random access memory (DRAM)), where the volatile memory may include volatile memory cells. In some cases, a host device may avoid accessing one or more of the volatile memory cells within the system. For example, some quantity of the volatile memory cells may be defective (e.g., due to manufacturing defects). Memory cells may be considered defective if they are stuck in one state or another, are prone to being read back incorrectly, or otherwise are determined to fail a reliability test (e.g., post-fabrication).

In some cases, to prevent defective memory cells from affecting performance of a memory device (and thus the broader system), the memory device may include redundant (e.g., spare) cells that are configured to replace defective cells in a way that is not known or detectable by host device. For instance, when the host device transmits a command to access (e.g., read from or write to) a defective memory cell, a memory device may instead access a replacement memory cell, without alerting the host device of the substitution. But the quantity of defective cells that may be replaced by redundant cells may be limited. For instance, both the redundant cells and associated circuitry (e.g., fuses or anti-fuses to activate and configure use of the redundant cells) may take up space within a memory device. Accordingly, the quantity of redundant cells may be limited to avoid excessively increasing a size of the memory device or system, which may limit the extent to which defective memory cells may be repaired via a replacement scheme, whether at the factory, when a system is being assembled, or when a system is operating.

As described herein, however, a host device may receive information from one or more memory devices within the system about memory cells (e.g., defective memory cells) that the host device is to avoid accessing (e.g., reading data from or writing data to). For example, one or more non-volatile memory devices within the system may store information about defective or otherwise to-be-avoided memory cells within the system (e.g., volatile memory cells, or other non-volatile memory cells, or both). The host device may receive, from the one or more non-volatile memory devices, an indication of the memory cells that the host device is to avoid accessing, and the host device may accordingly avoid accessing the indicated memory cells. Thus, for example, rather than accounting for defective memory cells using a limited number of replacement memory cells, a host device may avoid accessing any quantity of indicated memory cells. In some cases, for example, the host device may receive (e.g., from a non-volatile memory device) the indication of one or more memory cells (e.g., within a volatile memory device) that the host device is to avoid upon a boot or reboot of the system. Where the memory cells to be avoided are volatile memory cells, storing information indicative of the memory cells to be avoided (e.g., associated addresses) in non-volatile memory may allow such information to be programmed and retained in the absence of system power, such as before shipping the volatile memory and associated non-volatile memory to a customer, as part of a same device, die, package, or module.

The teachings herein may be applied to systems including a variety of memory types and architectures. As one example, if a system includes a dual in-line memory module (DIMM) that includes volatile memory (e.g., DRAM), the system may store information about defective or otherwise to-be-avoided volatile memory cells within a serial presence detect (SPD) memory of the DIMM, where the SPD memory may be non-volatile (e.g., may be SPD electrical erasable programmable read-only memory (EEPROM)). As another example, both volatile memory and non-volatile memory may be included within a single package, such as with the volatile memory included on one or more chips (e.g., dies) and non-volatile memory (e.g., NOT-AND (NAND) memory) included on one or more other chips (e.g., dies), with information about defective or otherwise to-be-avoided cells of the volatile memory stored within the non-volatile memory. Such an architecture may be referred to as a multi-chip package (MCP) architecture. As yet another example, a system may include both volatile and non-volatile memory on a single chip (e.g., die), which may be referred to as a single-chip package (SCP) architecture, and the system may store information about defective or otherwise to-be-avoided cells of the volatile memory within non-volatile memory on the same chip.

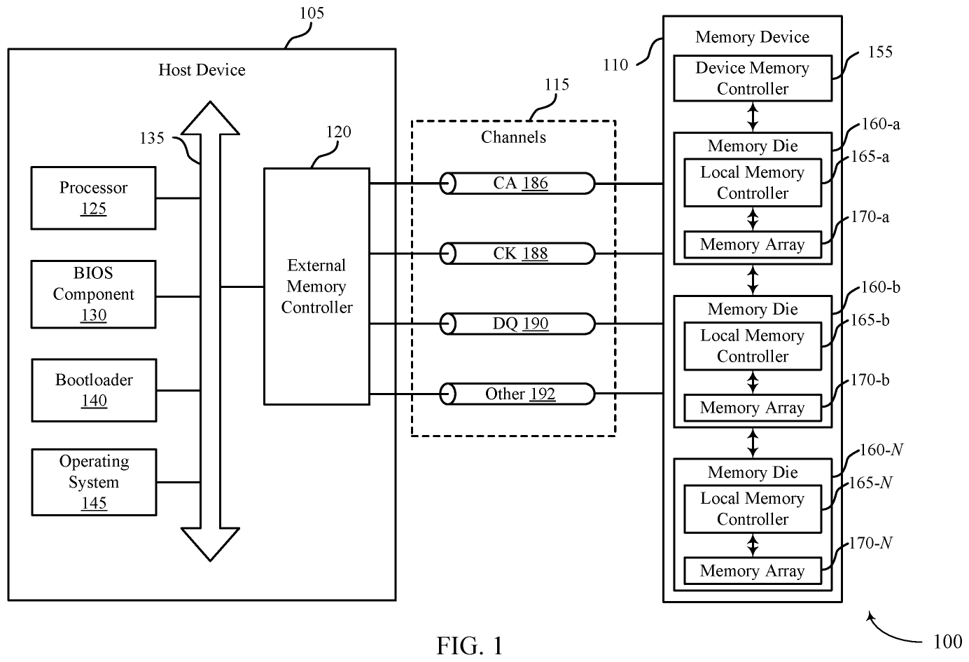

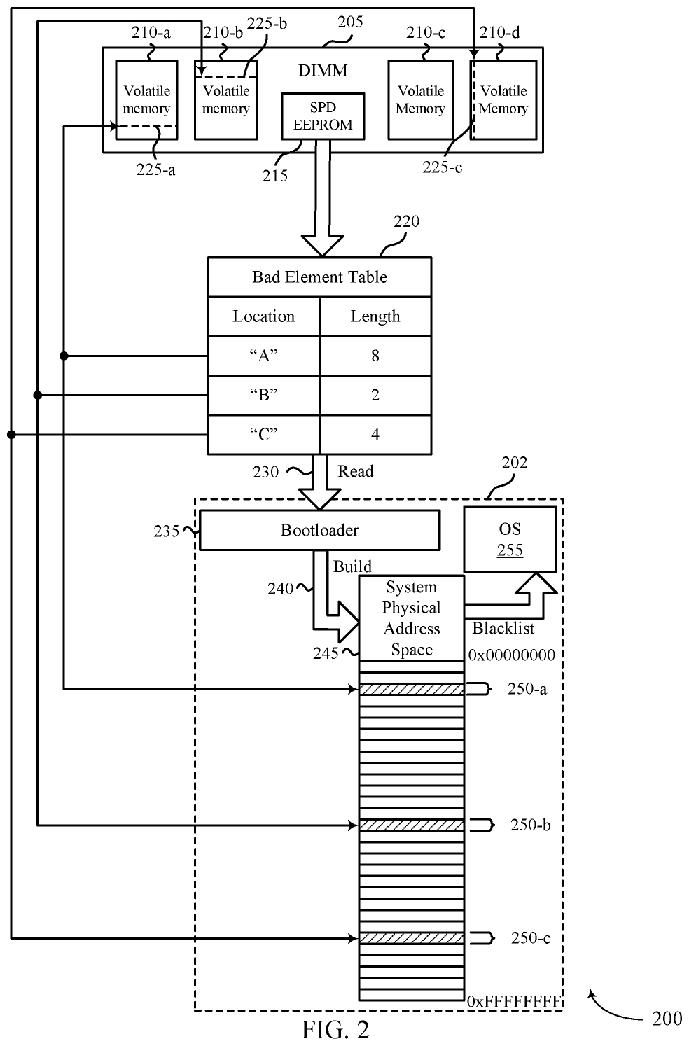

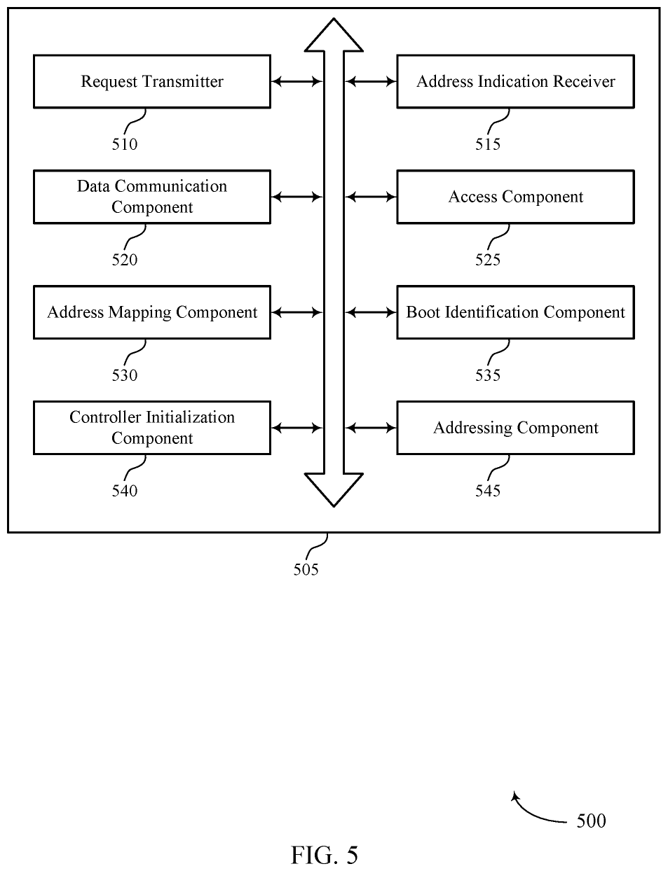

Features of the disclosure are initially described in the context of an example system as described with reference to FIG. 1. Features of the disclosure are further described in the context of example address indication schemes and example architectures as described with reference to FIGS. 2-4. These and other features of the disclosure are further illustrated by and described with reference to example apparatus diagrams and flowcharts that relate to indication-based avoidance of defective memory cells as described with reference to FIGS. 5-8. Though various examples may be described herein in the context of a host device avoiding accessing defective memory cells, it is to be understood that the teachings herein may be extended to avoid accessing one or more memory cells for any reason.

FIG. 1 illustrates an example of a system 100 that supports indication-based avoidance of defective memory cells in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system operable to store data for one or more other components of the system 100.

At least portions of the system 100 may be examples of the host device 105. The host device 105 may be an example of a processor or other circuitry within a device that uses memory to execute processes, such as within a computing device, a mobile computing device, a wireless device, a graphics processing device, a graphics processing unit (GPU), a computer, a laptop computer, a tablet computer, a smartphone, a cellular phone, a wearable device, an internet-connected device, a vehicle controller, a system on a chip (SoC), or some other stationary or portable electronic device, among other examples.

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other factors.

The memory device 110 may be operable to store data for the components of the host device 105. In some examples, the memory device 110 may act as a slave-type device to the host device 105 (e.g., responding to and executing commands provided by the host device 105, such as through the external memory controller 120). Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, a bootloader 140, an operating system 145, or other components such as one or more peripheral components or one or more input/output controllers. The components of host device 105 may be coupled with one another using a bus 135.

The processor 125 may be operable to provide control or other functionality for at least portions of the system 100 or at least portions of the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or a combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The external memory controller 120 may be operable to enable communication of one or more of information, data, or commands between components of the system 100 or the host device 105 (e.g., the processor 125) and the memory device 110. The external memory controller 120 may convert or translate communications exchanged between the components of the host device 105 and the memory device 110. In some examples, the external memory controller 120 or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The BIOS component 130 may be a software or firmware component, which may initialize and run various hardware components of the system 100 or the host device 105. The BIOS component 130 may also manage data flow between the processor 125 and the various components of the system 100 or the host device 105. The BIOS component 130 may include a program or software stored in one or more of read-only memory (ROM), flash memory, or other non-volatile memory. In some cases, code included in the BIOS component 130 may be executed by the processor 125.

In some examples, after the host device 105 boots up, the host device 105 may operate the system 100 according to the operating system 140. The operating system may be a software component that includes code configured to be executed by the processor 125 to operate and manage various hardware and software components of the system 100. The operating system 140 may include a set of instructions executable by the processor 125 and stored in non-volatile memory within the system 100, such as a hard drive or NAND memory, which may be included in or separate from the memory device 110.

The bootloader 140 may be a software or firmware component, which may be executed (e.g., by the processor 125) to initialize the operating system 145 or other software components (e.g., after code included in the BIOS component 130 is executed). For example, when executed, the bootloader 140 may write some or all of the operating system 145 into volatile memory within the memory device 110 (e.g., after reading the operating system 145 code from non-volatile memory). Though illustrated separately in the example of FIG. 1, in some cases, the bootloader 140 may be included in or otherwise combined with the BIOS component 130.

The memory device 110 may include a device memory controller 155 and one or more memory dies 160 (e.g., memory chips) to support a desired capacity or a specified capacity for data storage. Each memory die 160 may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store at least one bit of data.

The device memory controller 155 may include circuits, logic, or components operable to control operation of the memory device 110. The device memory controller 155 may include the hardware, the firmware, or the instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

In some examples, the memory device 110 may receive data or commands or both from the host device 105. For example, the memory device 110 may receive a write command indicating that the memory device 110 is to store data for the host device 105 or a read command indicating that the memory device 110 is to provide data stored in a memory die 160 to the host device 105.

A local memory controller 165 (e.g., local to a memory die 160) may include circuits, logic, or components operable to control operation of the memory die 160. In some examples, a local memory controller 165 may be operable to communicate (e.g., receive or transmit data or commands or both) with the device memory controller 155. A memory device 110 may not include a device memory controller 155, and a local memory controller 165, or the external memory controller 120 may perform various functions described herein. As such, a local memory controller 165 may be operable to communicate with the device memory controller 155, with other local memory controllers 165, or directly with the external memory controller 120, or the processor 125, or a combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other circuits or controllers operable for supporting described operations of the device memory controller 155 or local memory controller 165 or both.

The components of the host device 105 may exchange information with the memory device 110 using one or more channels 115. The channels 115 may be operable to support communications between the external memory controller 120 and the memory device 110. Each channel 115 may be examples of transmission mediums that carry information between the host device 105 and the memory device. Each channel 115 may include one or more signal paths or transmission mediums (e.g., conductors) between terminals associated with the components of system 100. A signal path may be an example of a conductive path operable to carry a signal. For example, a channel 115 may include a first terminal including one or more pins or pads at the host device 105 and one or more pins or pads at the memory device 110. A pin may be an example of a conductive input or output point of a device of the system 100, and a pin may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or a combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

When the system 100 boots, the bootloader 140 may include a routine for initializing one or more memory controllers coupled with the processor 125 (e.g., external memory controller 120). For example, initializing the external memory controller 120 may include querying the memory device 110 to retrieve timing parameters or topology parameters (e.g., rank count) for the memory device 110. For example, the memory device 110 may include volatile memory (e.g., DRAM) and also non-volatile memory (e.g., NAND or EEPROM), and the non-volatile memory may be queried to obtain information regarding the volatile memory.

After initialization of the external memory controller 120, a logical address space addressable by the host device 105 (which may alternatively be referred to as a virtual or system address space) may be viable for addressing commands to the memory device 110, which may translate the logical addresses into a corresponding physical address space associated with a set of memory cells (e.g., volatile memory cells) at the memory device 110. For instance, after initialization of the external memory controller 120, the processor 125 or external memory controller 120 may read or otherwise obtain executable instructions associated with other programs (e.g., applications) from non-volatile memory (which may be included in or separate from the memory device 100, depending on implementation) and may write such executable instructions to the memory device 110. The processor 125 or external memory controller 120 thereafter may read and execute instructions from the memory device 110 (based on commands addressed to the associated logical address space) and may also write and read to and from the memory device 110 (based on commands addressed to the associated logical address space).

In some cases, the system 100 or an associated component or program (e.g., application) may suffer an error condition or even crash if information (e.g., executable instructions or data) written to the memory device 110 is not accurately read back from the memory device 110. Such errors may occur, for example, if information is written to one or more defective memory cells within the memory device 110. Thus, as described herein, if the host device 105 identifies memory cells within the memory device 110 that the host device 105 is to avoid accessing (e.g., to avoid writing to or reading from), such as defective memory cells, and the host device 105 avoids accessing such memory cells, the likelihood of such errors may be decreased, and the reliability of the system 100 may be increased, among other benefits that may be appreciated by one of ordinary skill in the art. For example, configuring the host device 105 to receive an indication of defective or otherwise to-be-avoided memory cells may render usable, for at least some applications, a memory device 110 that has a larger quantity of defective memory cells than is repairable via a limited quantity of redundant or spare memory cells included in the memory device 110, which may improve production yields or provide other economic benefits.

In accordance with the teachings herein, information about (e.g., addresses of) one or more defective volatile memory cells within a memory device 110 may be stored within non-volatile memory of the system 100, where such non-volatile memory may be included in or separate from the memory device 110. The host device 105 may be configured to query the non-volatile memory for an indication of the one or more defective volatile memory cells and to thereafter avoid accessing the indicated volatile memory cells. In some cases, the bootloader 140 may be configured to execute such a query as part of a boot routine for the system 100. For instance, if the memory device 110 is a DIMM, then the host device 105 (e.g., the bootloader 140) may be configured to request the indication of the one or more defective addresses from an SPD EEPROM included in the DIMM, where the SPD EEPROM may also store and provide indications of one or more operating (e.g., timing or topological) parameters for the volatile memory within the DIMM. As another example, the memory device 110 may include non-volatile (e.g., NAND) memory on a same or different memory die 160 as a volatile (e.g., DRAM) memory 170, and the host device 105 (e.g., the bootloader 140) may be configured to request the indication of the one or more defective addresses from such non-volatile memory. In some cases, the external memory controller 120 may not be initialized until after the host device 105 has obtained information regarding the memory cells within the memory device 110 to be avoided.

FIG. 2 illustrates an example of a memory architecture 200 that supports indication-based avoidance of defective memory cells in accordance with examples as disclosed herein. In some examples, memory architecture 200 may represent a scheme by which a system may communicate addresses to avoid accessing to a host device (e.g., a host device 105 as described with reference to FIG. 1) and by which the host device may map the received addresses to a set of system physical addresses.

Memory architecture 200 may include a DIMM 205. The DIMM 205 may include one or more instances of volatile memory 210-a, 210-b, 210-c, and 210-d (e.g., DRAM devices). In some examples, each instance of volatile memory 210 may be an example of a memory device 110 or memory die 160 as described with reference to FIG. 1. The instances of volatile memory 210 may be configured to store data that is maintained while the DIMM 205 is in an active state (e.g., powered on). Additionally, the DIMM 205 may include non-volatile memory (e.g., an SPD EEPROM 215). The non-volatile memory may be configured to retain data whether the DIMM 205 is in an active state (e.g., powered on) or an inactive state (e.g., powered off or disconnected from a power source).

Memory architecture 200 may also include host device 202, which may be an example of a host device 105 as described with reference to FIG. 1. The host device 202 may include a bootloader 235, which may be an example of a bootloader 140 as described with reference to FIG. 1. The host device 202 may address commands, data, or other signaling exchanged with the DIMM 205 using addresses within a system physical address space 245 (e.g., logical address space), which may represent a set of system physical addresses 250 (e.g., logical addresses). Additionally, the host device 202 may include an operating system 255, which may be an example of operating system 145 as described with reference to FIG. 1.

The SPD EEPROM 215 may be configured to store a table 220 that includes information about one or more defective cells or sets of cells (e.g., rows, columns, banks)-which may generically be referred to as defective memory locations 225—among the instances of volatile memory 210 (i.e., a bad memory element table (BMET)). For instance, the SPD EEPROM 215 may store information corresponding to a first defective memory location 225-a of volatile memory instance 210-a; a second defective memory location 225-b of volatile memory instance 210-b; and a third defective memory location 225-c of volatile memory instance 210-d. In some examples, the table 220 may include an entry for each defective memory location 225 and a length corresponding to the quantity of contiguous defective cells, rows, columns, banks, or bits in that defective memory location 225. For instance, defective memory location 225-a may correspond to 8 defective cells, rows, columns, or banks; defective memory location 225-b may correspond to 2 defective cells, rows, columns, or banks; and defective memory location 225-c may correspond to 3 defective cells, rows, columns, or banks.

In some examples, the SPD EEPROM 215 may be configured to provide an indication of the one or more defective volatile memory cells to a host device 202. For instance, a bootloader 235 of the host device 202 may provide instructions for that, when executed at the host device 202, cause the host device 202 to transmit a request to the SPD EEPROM 215 for the indication of the one or more defective cells. The request, for instance, may include a read command or other query for the SPD EEPROM 215. Upon receiving the request, the SPD EEPROM 215 may retrieve information corresponding to the one or more defective cells (e.g., the table 220) and may provide an indication of the one or more defective cells (e.g., an indication of the table 220) to the host device 202.

The host device 202 may map (e.g., based on executing the bootloader 235), each of the defective memory locations 225 to a corresponding system physical address 250 within the system physical address space 245. For instance, the defective memory locations 225 may each be indicated (e.g., via the table 220) by a corresponding address within a physical address space associated with the DIMM 205 or a volatile memory 210 therein, and the bootloader 235 may include code that instructs a processor of the host device 202 (e.g., processor 125) to map a respective physical address for each defective memory location 225 to a respective system physical address 250. For instance, the host device 202 may map defective memory location 225-a to system physical address 250-a; defective memory location 225-b to system physical address 250-b; and defective memory location 225-c to system physical address 250-c. Thus, for example, the memory locations 225 may be defined relative to the volatile memory instance 210 within which the memory locations 225 reside and may each be in a first address space (e.g., physical address space) of their respective volatile memory instances 210. Meanwhile, the system physical addresses 250 may be defined relative to the system physical address space 245 and may thus be in a second address space (e.g., logical address space). As such, mapping the memory locations 225 to respective system physical addresses 250 may involve mapping from the first address space to the second address space.

After mapping the memory locations 225 to respective system physical addresses 250, the bootloader 235 may cause the host device 202 to provide a corresponding indication (e.g., a blacklist) of the respective system physical addresses 250 (e.g., system physical addresses 250-a, 250-b, and 250-c) to the operating system 255. The operating system 255, after receiving the blacklist, may sequester (e.g., refrain from causing the host device 202 to read from, write to, or otherwise access or utilize) the indicated system physical addresses 250 such that the operating system 255 does not utilize the corresponding defective memory locations 225. For example, the operating system 255 may not allocate the corresponding system physical addresses 250 to any applications. In some examples, the operating system 255 (or a processor, such as a CPU, included in the host device 202) may mark these system physical addresses 250 as reserved, which may prohibit exposure to them and associated attendant errors. In some examples, a controller for the DIMM 205 that is included in or coupled with the host device 202 (e.g., a host-side DRAM controller) may not be initialized (e.g., by the bootloader 235) until after the system physical addresses 250 to be avoided have been provided to the operating system 255, or at least have been obtained by the host device 202.

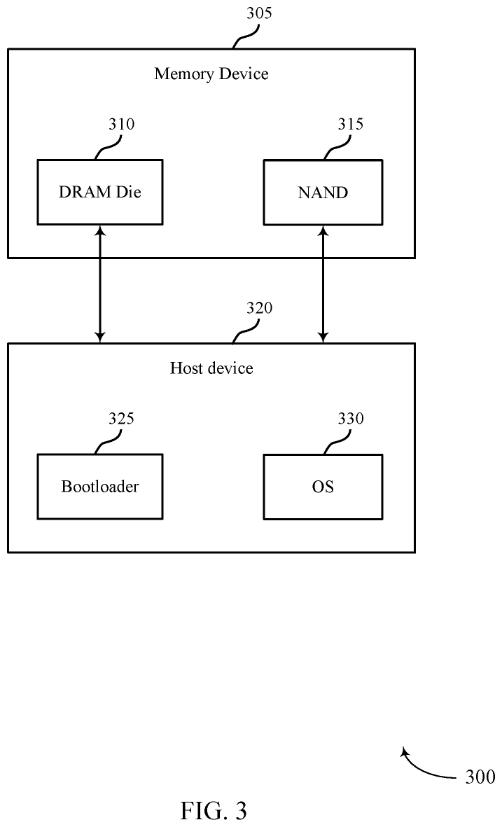

FIG. 3 illustrates an example of a device communication configuration 300 that supports indication-based avoidance of defective memory cells in accordance with examples as disclosed herein. In some examples, memory architecture 300 may be implemented by one or more components of FIG. 1 or 2 For instance, memory device 305 may be an example of a memory device 110 as described with reference to FIG. 1 or an instance of volatile memory 210 as described with reference to FIG. 2, and host device 320 may be an example of a host device 105 as described with reference to FIG. 1 or a host device 202 as described.

Memory architecture 300 may include a memory device 305. Memory device 305 may include a DRAM die 310, which may be an example of volatile memory, and NAND memory 315, which may be an example of non-volatile memory. The DRAM die 310 may be an example of a memory die 160 as described with reference to FIG. 1. The DRAM die 310 and the NAND memory 315 may be included in a same package. However, in some examples, the DRAM die 310 may be on a first die (which may be referred to as a chip) and the NAND memory 315 may be on a second die. In such cases, the memory device may be considered an MCP.

Memory architecture 300 may also include a host device 320. Host device 320 may include a bootloader 325 and operating system 330. Bootloader 325 may be an example of a bootloader 140 as described with reference to FIG. 1 or a bootloader 235 as described with reference to FIG. 2. Operating system 330 may be an example of an operating system 255 as described with reference to FIG. 2.

In some examples, memory device 305 may be configured to communicate with host device 320. For instance, DRAM die 310 may communicate with host device 320 over a first interface (e.g., a first bus or set of pins) and NAND memory 315 may communicate with the host device 320 over a second interface (e.g., a second bus or set of pins). The communications between the memory device 305 and the host device 320 may include commands (e.g., commands for accessing the DRAM die 310 or the NAND memory 315) or data (e.g., data to be written to the DRAM die 310 or read from the DRAM die 310 or the NAND memory 315).

In the present example, the NAND memory 315 may be configured to store a table (e.g., the table 220 as described with reference to FIG. 2) that includes information about one or more defective cells among the DRAM die 310 (i.e., a BMET). For instance, the NAND memory 315 may store information corresponding to a first memory location of the DRAM die 310, a second memory location of the DRAM die 310, and a third memory location of the DRAM die 310. The table may include an entry for each memory location and a length corresponding to the quantity of contiguous defective cells, rows, or columns in that memory location, for example. In some examples, the memory device 305 may include multiple DRAM dies 310. In such examples, the memory locations included in the table may come from one or more of the multiple DRAM dies 310.

In some examples, the NAND memory 315 may be configured to provide an indication of the one or more defective cells to the host device 320. For instance, a bootloader 325 of the host device 320 may provide instructions for the host device 320 to transmit a request for the indication of the one or more defective cells. The request, for instance, may include a read command for the NAND memory 315. Upon receiving the request, the NAND memory 315 may retrieve information corresponding to the one or more defective cells (e.g., a table, such as the table 220 as described with reference to FIG. 2) and may provide an indication of the one or more defective cells (e.g., an indication of the table 220) to the host device 320 including the bootloader 325. In some examples, the table may have a specific placement (e.g., the first N pages of erase block 0). And in some examples, the driver software for the NAND memory 315 may identify that the table is for the DRAM die 310.

Using the bootloader 325, the host device 320 may map provided memory locations to physical memory, such as described with reference to FIG. 2. For instance, the bootloader 325 may include code that instructs a processor of the host device 320 (e.g., processor 125) to map each memory location which may be indicated in terms of a physical address within a physical address space of the DRAM die 310, to a respective system physical address of an address space used by the host device 320. For instance, the host device 320 may map a first memory location to a first system physical address; a second memory location to a second system physical address; and a third memory location to a third system physical address. Thus, for example, the memory locations as indicated by the NAND memory 315 may be defined relative to the DRAM die 310 within which the memory locations may reside and may each be in a first address space of the DRAM die 310. Meanwhile, the system physical addresses may be defined relative to the physical memory and may thus be in a second address space of the physical memory. As such, mapping the memory locations to respective physical addresses may involve mapping from the first address space to the second address space.

After mapping the memory locations to respective system physical addresses, the host device 320 may be instructed by the bootloader 325 to relay a blacklist of the respective system physical addresses to the operating system 330 of the host device 320. The operating system 330, after receiving the blacklist, may sequester the indicated system physical addresses such that the operating system 330 does not utilize the system physical addresses and the operating system 330 does not allocate these addresses to applications.

In some examples, a controller for the DRAM die 310 that is included in or coupled with the host device 320 (e.g., a host-side DRAM controller) may not be initialized (e.g., by the bootloader 325) until after the system physical addresses to be avoided have been provided to the operating system 330, or at least have been obtained by the host device 320.

Though aspects of the example of FIG. 3 are described with reference to DRAM and NAND memory types, it is to be understood that the teachings herein may be applied to any memory types, including any combination of volatile and non-volatile memory within an MCP.

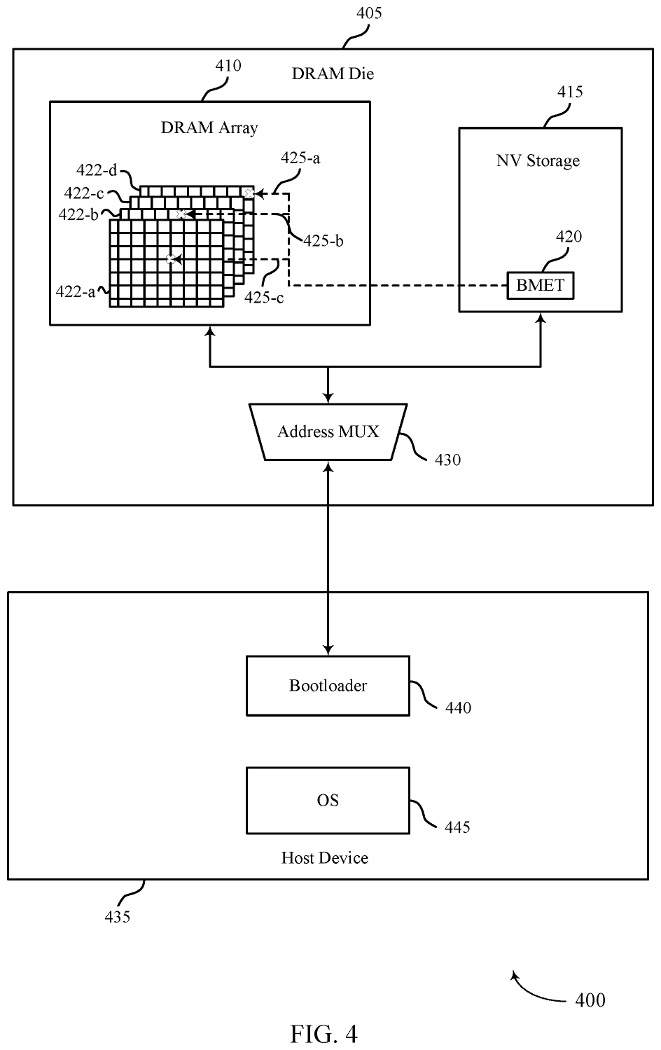

FIG. 4 illustrates an example of a device communication configuration 400 that supports indication-based avoidance of defective memory cells in accordance with examples as disclosed herein. In some examples, memory architecture 400 may be implemented by one or more components of FIGS. 1 through 3. For instance, DRAM die 405 may be an example of a memory die 160 as described with reference to FIG. 1, an instance of volatile memory 210 as described with reference to FIG. 2, or a DRAM die 310 as described with reference to FIG. 3. Additionally, host device 435 may be an example of a host device 105 as described with reference to FIG. 1 or a host device 202 as described with reference to FIG. 2.

Memory architecture 400 may include a DRAM die 405. DRAM die 405 may include a DRAM array 410, which may be an example of volatile memory. The DRAM array 410 may be an example of a memory array 170 as described with reference to FIG. 1. In some examples, the DRAM array 410 may include one or more banks 422. For instance, in the present example, the DRAM array 410 may include banks 422-a, 422-b, 422-c, and 422-d.

In some cases, DRAM die 405 includes a non-volatile storage 415, which may be an example of non-volatile memory. In some examples, non-volatile storage 415 may include programmable read-only memory (PROM), one or more fuses, one or more antifuses, or any other type of non-volatile memory, alone or in any combination. The DRAM die 405 may be included in a memory device (e.g., a memory device 110). DRAM die 405 may further include an address multiplexer (MUX) 430. In examples where the memory device includes a single instance of the DRAM die 405, the memory device may be considered an SCP.

Memory architecture 400 may also include a host device 435. Host device 435 may include a bootloader 440 and operating system 445. Bootloader 440 may be an example of a bootloader 140 as described with reference to FIG. 1, a bootloader 235 as described with reference to FIG. 2, or a bootloader 325 as described with reference to FIG. 3. Operating system 445 may be an example of an operating system 255 as described with reference to FIG. 2 or an operating system 330 as described with reference to FIG. 3.

DRAM array 410 and non-volatile storage 415 may be coupled with address MUX 430. Address MUX 430 may further be couplable with host device 435. For instance, address MUX 430 may be coupled with a memory controller of the host device 435 configured to execute code corresponding to a bootloader 440, an operating system 445, or both.

The address MUX 430, which may also be referred to as multiplexing circuitry, may be configured to selectively route commands or other signaling to either DRAM array 410 or non-volatile memory storage 415. For example, the address MUX 430 may route signaling addressed to a first portion of an address space for memory die 405 to DRAM array 410, and the address MUX 430 may route signaling addressed to a second portion of the address space for the memory die 405 to non-volatile storage 415. For instance, when the host device 435 provides an command indicating to access a first set of rows of a bank of the DRAM array 410 (e.g., first N rows of a given bank), the address MUX 430 may route the command to non-volatile storage 415 rather than to the DRAM array 410. Though illustrated as included in the DRAM die 405 in the example of FIG. 4, one of ordinary skill in the art will appreciate that address MUX 430 may not be included in the DRAM die 405 in some implementations. For example, address MUX 430 and related concepts may be employed in an MCP example such as the example described with reference to FIG. 3.

In some examples, the non-volatile storage 415 may include a set of non-volatile mode registers. In some such examples, the bootloader 440 may query the non-volatile storage 415 by transmitting a read command addressed to the mode registers. In some such examples, the address space of the non-volatile storage 415 may be different from the address space of the DRAM array 410.

The non-volatile storage 415 may be configured to store information about one or more defective cells in the DRAM array 410, such as a table for example (e.g., BMET 420, which may be an example of the table 220 as described with reference to FIG. 2). For instance, the non-volatile storage 415 may store information corresponding to memory location 425-a at bank 422-d; memory location 425-b at bank 422-b; and memory location 425-c at bank 422-a. In some examples, the BMET 420 may include an entry for each memory location and a length corresponding to the quantity of contiguous defective cells, rows, or columns in that memory location 425.

In some examples, the non-volatile storage 415 may be configured to provide an indication of the one or more defective cells to the host device 435. For instance, a bootloader 440 of the host device 435 may provide instructions for the host device 435 to transmit a request for the indication of the one or more defective cells. The request, for instance, may include a read command for the non-volatile storage 415. Upon receiving the request, the non-volatile storage 415 may retrieve information corresponding to the one or more defective cells (e.g., a table, such as the BMET 420) and may provide an indication of the one or more defective cells (e.g., an indication of the BMET 420) to the host device 435 including the bootloader 440.

Using the bootloader 440, the host device 435 may map provided memory locations from a physical address space associated with the DRAM array 410 to a system physical address space (e.g., virtual address space) associated with the host device 435, such as described with reference to FIG. 2. For instance, the bootloader 440 may include code that instructs a processor of the host device 435 (e.g., processor 125) to map each respective address for each defective memory location to a respective system physical address. For instance, the host device 435 may map a first defective memory location to a first system physical address; a second defective memory location to a second system physical address; and a third defective memory location to a third system physical address. Thus, for example, the defective memory locations may be defined relative to the DRAM array 410 within which the memory locations may reside and may each be in a first address space of the DRAM array 410. Meanwhile, the system physical addresses may be defined relative to a second address space used by the host device 435 to address commands or other signaling to the DRAM die 405. As such, mapping the memory locations to respective system physical addresses may involve mapping from the first address space to the second address space.

After mapping the memory locations to respective system physical addresses, the host device 435 may be instructed by the bootloader 440 to relay a blacklist of the respective system physical addresses to the operating system 445 of the host device 435. The operating system 445, after receiving the blacklist, may sequester the indicated system physical addresses such that the operating system 445 does not utilize the system physical addresses and the operating system 445 does not allocate these addresses to applications.

In some examples, a controller for the DRAM die 405 or the DRAM array 410 that is included in or coupled with the host device 435 (e.g., a host-side DRAM controller) may not be initialized (e.g., by the bootloader 440) until after the system physical addresses to be avoided have been provided to the operating system 445, or at least have been obtained by the host device 435.

Though aspects of the example of FIG. 4 are described with reference to DRAM and NAND memory types, it is to be understood that the teachings herein may be applied to any memory types, including any combination of volatile and non-volatile memory within an SCP.

FIG. 5 shows a block diagram 500 of a host device 505 that supports indication-based avoidance of defective memory cells in accordance with examples as disclosed herein. The host device 505 may be an example of aspects of a host device as described with reference to FIGS. 1 through 4. The host device 505 may include a request transmitter 510, an address indication receiver 515, a data communication component 520, an access component 525, an address mapping component 530, a boot identification component 535, a controller initialization component 540, and an addressing component 545. Each of these modules may communicate, directly or indirectly, with one another (e.g., via one or more buses).

The request transmitter 510 may transmit, from a host device to a non-volatile memory component, a request for an indication of one or more addresses of a volatile memory component coupled with the host device, the one or more addresses for the host device to avoid accessing. In some examples, transmitting the request to the non-volatile memory component may include querying the non-volatile memory component for serial presence detect (SPD) information about the volatile memory component.

In some cases, the host device includes a bootloader, where the bootloader transmits the request for the indication of the one or more addresses.

The address indication receiver 515 may receive, at the host device from the non-volatile memory component, the indication of the one or more addresses of the volatile memory component for the host device to avoid accessing.

The data communication component 520 may communicate, by the host device, data with the volatile memory component.

The access component 525 may refrain, by the host device and based on the indication received from the non-volatile memory component, from writing to or reading from the one or more addresses of the volatile memory component while communicating the data with the volatile memory component.

In some examples, the one or more addresses may be within a first address space associated with the volatile memory component. In some such examples, the address mapping component 530 may map the one or more addresses to one or more corresponding addresses within a second address space associated with the host device, where the refraining by the host device includes sequestering the one or more corresponding addresses.

The boot identification component 535 may identify a boot or reboot of the host device, where transmitting the request for the indication of the one or more addresses is based on identifying the boot or reboot. The boot identification component 535 may, for example, be, be included in, or be coupled with a bootloader as described herein. In some examples, the bootloader may refrain from writing to or reading from the one or more addresses of the volatile memory component.

The controller initialization component 540 may initialize, at the host device, a controller for the volatile memory component after receiving (e.g., by the host device) the indication of the one or more addresses.

The addressing component 545 may address the request to one or more mode registers, where transmitting the request to the non-volatile memory component is based on the addressing. In some examples, the addressing component 545 may address the request to an address within a first portion of an address space for the volatile memory component, where the one or more addresses are within a second portion of the address space for the volatile memory component, and where transmitting the request to the non-volatile memory component is based on the addressing.

In some cases, the volatile memory component includes a set of volatile memory devices, where the one or more addresses include addresses for a set of volatile memory devices within the set of volatile memory devices. In some cases, the one or more addresses correspond to one or more defective memory cells within the volatile memory component. In some cases, the volatile memory component may include dynamic random access memory (DRAM). In some cases, the non-volatile memory component may include NOT-AND (NAND) memory.

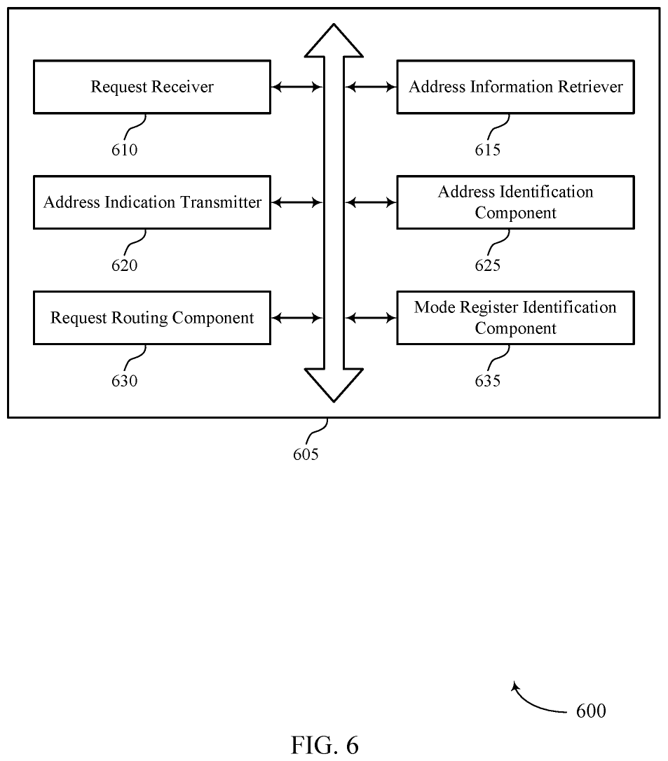

FIG. 6 shows a block diagram 600 of a memory device 605 that supports indication-based avoidance of defective memory cells in accordance with examples as disclosed herein. The memory device 605 may be an example of aspects of a memory device as described with reference to FIGS. 1 through 4. The memory device 605 may include a request receiver 610, an address information retriever 615, an address indication transmitter 620, an address identification component 625, a request routing component 630, and a mode register identification component 635. Each of these modules may communicate, directly or indirectly, with one another (e.g., via one or more buses).

The request receiver 610 may receive, from a host device, a request for an indication of one or more addresses of a volatile memory component, the one or more addresses for the host device to avoid accessing. In some cases, the volatile memory component includes dynamic random access memory (DRAM). In some cases, the volatile memory component includes dynamic random access memory (DRAM) on a first die within a package.

The address information retriever 615 may retrieve, based on the request, information from a non-volatile memory component that indicates the one or more addresses of the volatile memory component for the host device to avoid accessing. In some cases, the non-volatile memory component stores serial presence detect (SPD) information for the DRAM, the SPD information including the information that indicates the one or more addresses. In some cases, the non-volatile memory component includes NOT-AND (NAND) memory on a second die within the package. In some cases, the non-volatile memory component includes one-time programmable memory. In some cases, the volatile memory component and the non-volatile memory component are on a same die.

The address indication transmitter 620 may transmit, to the host device, the indication of the one or more addresses of the volatile memory component for the host device to avoid accessing.

The address identification component 625 may identify an address associated with the request. The request routing component 630 may route the request to the non-volatile memory component based on the address associated with the request, where the address associated with the request is within a first portion of an address space for the volatile memory component, and where the one or more addresses are within a second portion of the address space for the volatile memory component.

In some cases, the mode register identification component 635 may identify one or more mode registers based on the request, where the non-volatile memory component includes the one or more mode registers.

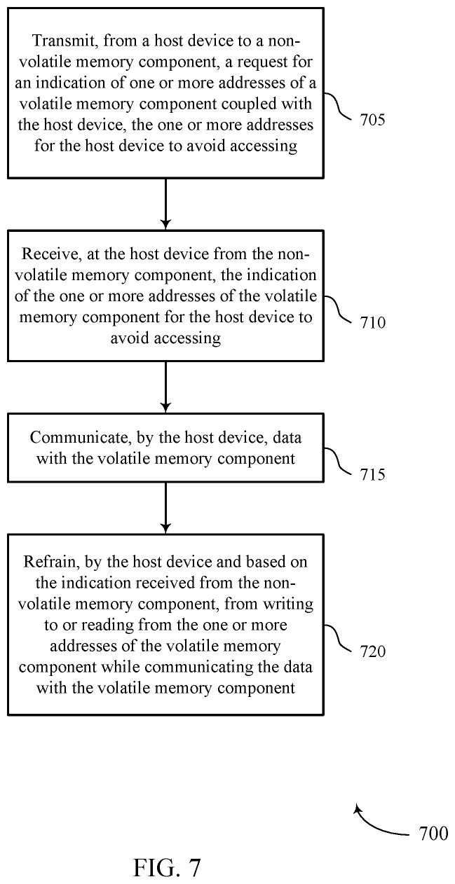

FIG. 7 shows a flowchart illustrating a method or methods 700 that supports indication-based avoidance of defective memory cells in accordance with examples as disclosed herein. The operations of method 700 may be implemented by a host device or its components as described herein. For example, the operations of method 700 may be performed by a host device as described with reference to FIG. 5. In some examples, a host device may execute a set of instructions to control the functional elements of the host device to perform the described functions. Additionally or alternatively, a host device may perform aspects of the described functions using special-purpose hardware.

At 705, the host device may transmit, to a non-volatile memory component, a request for an indication of one or more addresses of a volatile memory component coupled with the host device, the one or more addresses for the host device to avoid accessing. The operations of 705 may be performed according to the methods described herein. In some examples, aspects of the operations of 705 may be performed by a request transmitter as described with reference to FIG. 5.

At 710, the host device may receive, from the non-volatile memory component, the indication of the one or more addresses of the volatile memory component for the host device to avoid accessing. The operations of 710 may be performed according to the methods described herein. In some examples, aspects of the operations of 710 may be performed by an address indication receiver as described with reference to FIG. 5.

At 715, the host device may communicate (e.g., transmit or receive) data with the volatile memory component. The operations of 715 may be performed according to the methods described herein. In some examples, aspects of the operations of 715 may be performed by a data communication component as described with reference to FIG. 5.

At 720, the host device may refrain, based on the indication received from the non-volatile memory component, from writing to or reading from (e.g., from transmitting write or read commands addressed to) the one or more addresses of the volatile memory component while communicating the data with the volatile memory component. The operations of 720 may be performed according to the methods described herein. In some examples, aspects of the operations of 720 may be performed by an access component as described with reference to FIG. 5.

In some examples, an apparatus as described herein may perform a method or methods, such as the method 700. The apparatus may include features, means, or instructions (e.g., a non-transitory computer-readable medium storing instructions executable by a processor) for transmitting, from a host device to a non-volatile memory component, a request for an indication of one or more addresses of a volatile memory component coupled with the host device, the one or more addresses for the host device to avoid accessing. The apparatus may further include operations, features, means, or instructions for receiving, at the host device from the non-volatile memory component, the indication of the one or more addresses of the volatile memory component for the host device to avoid accessing. The apparatus may further include operations, features, means, or instructions for communicating, by the host device, data with the volatile memory component. The apparatus may further include operations, features, means, or instructions for refraining, by the host device and based on the indication received from the non-volatile memory component, from writing to or reading from the one or more addresses of the volatile memory component while communicating the data with the volatile memory component.

In some examples of the method 700 and the apparatus described herein, the one or more addresses may be within a first address space associated with the volatile memory component, and the apparatus may further include operations, features, means, or instructions for mapping the one or more addresses to one or more corresponding addresses within a second address space associated with the host device, where the refraining by the host device may include operations, features, means, or instructions for sequestering the one or more corresponding addresses.

Some examples of the method 700 and the apparatus described herein may further include operations, features, means, or instructions for identifying a boot or reboot of the host device, where transmitting the request for the indication of the one or more addresses may be based on identifying the boot or reboot.

Some examples of the method 700 and the apparatus described herein may further include operations, features, means, or instructions for initializing, at the host device, a controller for the volatile memory component after receiving the indication of the one or more addresses.

In some examples of the method 700 and the apparatus described herein, the host device may include a bootloader, where the bootloader transmits the request for the indication of the one or more addresses.

Some examples of the method 700 and the apparatus described herein may further include operations, features, means, or instructions for refraining, by the bootloader, from writing to or reading from the one or more addresses of the volatile memory component.

In some examples of the method 700 and the apparatus described herein, the volatile memory component may include a set of volatile memory devices, where the one or more addresses include addresses for (e.g., for memory cells across) multiple volatile memory devices within the set of volatile memory devices.

In some examples of the method 700 and the apparatus described herein, the one or more addresses may correspond to one or more defective memory cells within the volatile memory component.

In some examples of the method 700 and the apparatus described herein, th operations, features, means, or instructions for transmitting the request to the non-volatile memory component may include operations, features, means, or instructions for querying the non-volatile memory component for serial presence detect (SPD) information about the volatile memory component.

In some examples of the method 700 and the apparatus described herein, the volatile memory component may include dynamic random access memory (DRAM), and the non-volatile memory component may include NOT-AND (NAND) memory.

Some examples of the method 700 and the apparatus described herein may further include operations, features, means, or instructions for addressing the request to one or more mode registers, where transmitting the request to the non-volatile memory component may be based on the addressing.

Some examples of the method 700 and the apparatus described herein may further include operations, features, means, or instructions for addressing the request to an address within a first portion of an address space for the volatile memory component, where the one or more addresses may be within a second portion of the address space for the volatile memory component, and where transmitting the request to the non-volatile memory component may be based on the addressing.

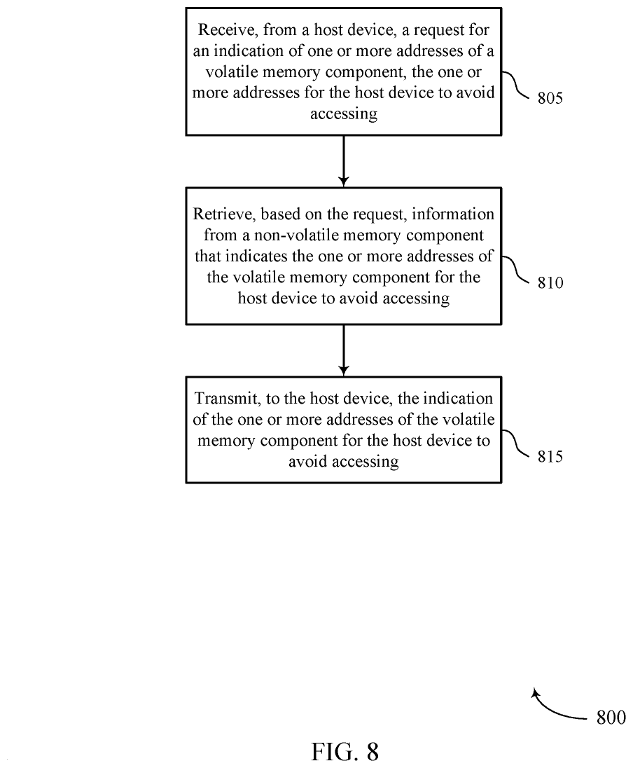

FIG. 8 shows a flowchart illustrating a method or methods 800 that supports indication-based avoidance of defective memory cells in accordance with examples as disclosed herein. The operations of method 800 may be implemented by a memory device or its components as described herein. For example, the operations of method 800 may be performed by a memory device as described with reference to FIG. 6. In some examples, a memory device may execute a set of instructions to control the functional elements of the memory device to perform the described functions. Additionally or alternatively, a memory device may perform aspects of the described functions using special-purpose hardware.

At 805, the memory device may receive, from a host device, a request for an indication of one or more addresses of a volatile memory component, the one or more addresses for the host device to avoid accessing. The operations of 805 may be performed according to the methods described herein. In some examples, aspects of the operations of 805 may be performed by a request receiver as described with reference to FIG. 6.

At 810, the memory device may retrieve, based on the request, information from a non-volatile memory component that indicates the one or more addresses of the volatile memory component for the host device to avoid accessing. The operations of 810 may be performed according to the methods described herein. In some examples, aspects of the operations of 810 may be performed by an address information retriever as described with reference to FIG. 6.

At 815, the memory device may transmit, to the host device, the indication of the one or more addresses of the volatile memory component for the host device to avoid accessing. The operations of 815 may be performed according to the methods described herein. In some examples, aspects of the operations of 815 may be performed by an address indication transmitter as described with reference to FIG. 6.

In some examples, an apparatus as described herein may perform a method or methods, such as the method 800. The apparatus may include features, means, or instructions (e.g., a non-transitory computer-readable medium storing instructions executable by a processor) for receiving, from a host device, a request for an indication of one or more addresses of a volatile memory component, the one or more addresses for the host device to avoid accessing. The apparatus may further include features, means, or instructions for retrieving, based on the request, information from a non-volatile memory component that indicates the one or more addresses of the volatile memory component for the host device to avoid accessing. The apparatus may further include features, means, or instructions for transmitting, to the host device, the indication of the one or more addresses of the volatile memory component for the host device to avoid accessing.

In some examples of the method 800 and the apparatus described herein, the volatile memory component may include dynamic random access memory (DRAM), and the non-volatile memory component may store serial presence detect (SPD) information for the DRAM, the SPD information including the information that indicates the one or more addresses.

In some examples of the method 800 and the apparatus described herein, the volatile memory component may include dynamic random access memory (DRAM) on a first die within a package, and the non-volatile memory component may include NOT-AND (NAND) memory on a second die within the package.

In some examples of the method 800 and the apparatus described herein, the non-volatile memory component may include one-time programmable memory.

In some examples of the method 800 and the apparatus described herein, the volatile memory component and the non-volatile memory component may be on a same die.

Some examples of the method 800 and the apparatus described herein may further include operations, features, means, or instructions for identifying an address associated with the request, and routing the request to the non-volatile memory component based on the address associated with the request, where the address associated with the request may be within a first portion of an address space for the volatile memory component, and where the one or more addresses may be within a second portion of the address space for the volatile memory component.

Some examples of the method 800 and the apparatus described herein may further include operations, features, means, or instructions for identifying one or more mode registers based on the request, where the non-volatile memory component includes the one or more mode registers.

It should be noted that the methods described herein describe possible implementations, and that the operations and the steps may be rearranged or otherwise modified and that other implementations are possible. Further, portions from two or more of the methods may be combined.

An apparatus is described. The apparatus may include a volatile memory component and a non-volatile memory component. The non-volatile memory component may be configured to store information indicating one or more defective memory cells within the volatile memory component, receive a request for an indication of the one or more defective memory cells within the volatile memory component, and output, in response to the request, an indication of the one or more defective memory cells within the volatile memory component.

In some examples, the apparatus may include a memory module, the volatile memory component may include dynamic random access memory (DRAM) within the memory module, and the non-volatile memory component may include electrically erasable programmable read-only memory (EEPROM) within the memory module and configured to store serial presence detect (SPD) information for the DRAM that includes the information indicating the one or more defective memory cells within the volatile memory component.

In some examples, the apparatus may include a set of dies within a package, the volatile memory component may include dynamic random access memory (DRAM) on a first die of the set of dies, and the non-volatile memory component may include NOT-AND (NAND) memory on a second die of the set of dies.

In some examples, the apparatus may include a die that includes the volatile memory component and the non-volatile memory component.

In some examples, the non-volatile memory component may include one or more non-volatile mode registers.

Some examples of the apparatus may include multiplexing circuitry configured to route commands for (e.g., addressed to an address within) a first portion of an address space for the die to the volatile memory component and commands for (e.g., addressed to an address within) a second portion of the address space for the die to the non-volatile memory component.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
transmitting, from a host device to a non-volatile memory component, a request for an indication of one or more addresses of a volatile memory component coupled with the host device, the one or more addresses for the host device to avoid accessing;
receiving, at the host device from the non-volatile memory component, the indication of the one or more addresses of the volatile memory component for the host device to avoid accessing;
communicating, by the host device, data with the volatile memory component; and
refraining, by the host device and based at least in part on the indication received from the non-volatile memory component, from writing to or reading from the one or more addresses of the volatile memory component while communicating the data with the volatile memory component.

2. The method of claim 1, wherein the one or more addresses are within a first address space associated with the volatile memory component, further comprising:
mapping the one or more addresses to one or more corresponding addresses within a second address space associated with the host device, wherein the refraining by the host device comprises sequestering the one or more corresponding addresses.

3. The method of claim 1, further comprising:
identifying a boot or reboot of the host device, wherein transmitting the request for the indication of the one or more addresses is based at least in part on identifying the boot or reboot.

4. The method of claim 3, further comprising:
initializing, at the host device, a controller for the volatile memory component after receiving the indication of the one or more addresses.

5. The method of claim 3, wherein the host device comprises a bootloader, and wherein the bootloader transmits the request for the indication of the one or more addresses.

6. The method of claim 5, further comprising:
refraining, by the bootloader, from writing to or reading from the one or more addresses of the volatile memory component.

7. The method of claim 1, wherein the volatile memory component comprises a set of volatile memory devices, and wherein the one or more addresses comprise addresses for a plurality of volatile memory devices within the set of volatile memory devices.

8. The method of claim 1, wherein the one or more addresses correspond to one or more defective memory cells within the volatile memory component.

9. The method of claim 1, wherein transmitting the request to the non-volatile memory component comprises:
querying the non-volatile memory component for serial presence detect (SPD) information about the volatile memory component.

10. The method of claim 1, wherein:
the volatile memory component comprises dynamic random access memory (DRAM); and
the non-volatile memory component comprises NOT-AND (NAND) memory.

11. The method of claim 1, further comprising:
addressing the request to one or more mode registers, wherein transmitting the request to the non-volatile memory component is based at least in part on the addressing.

12. The method of claim 1, further comprising:
addressing the request to an address within a first portion of an address space for the volatile memory component, wherein the one or more addresses are within a second portion of the address space for the volatile memory component, and wherein transmitting the request to the non-volatile memory component is based at least in part on the addressing.

13. A method, comprising:
receiving, from a host device, a request for an indication of one or more addresses of a volatile memory component, the one or more addresses for the host device to avoid accessing;
retrieving, based at least in part on the request, information from a non-volatile memory component that indicates the one or more addresses of the volatile memory component for the host device to avoid accessing; and
transmitting, to the host device, the indication of the one or more addresses of the volatile memory component for the host device to avoid accessing.

14. The method of claim 13, wherein:
the volatile memory component comprises dynamic random access memory (DRAM); and
the non-volatile memory component stores serial presence detect (SPD) information for the DRAM, the SPD information comprising the information that indicates the one or more addresses.

15. The method of claim 13, wherein:
the volatile memory component comprises dynamic random access memory (DRAM) on a first die within a package; and
the non-volatile memory component comprises NOT-AND (NAND) memory on a second die within the package.

16. The method of claim 13, wherein the non-volatile memory component comprises one-time programmable memory.

17. The method of claim 13, wherein the volatile memory component and the non-volatile memory component are on a same die.

18. The method of claim 17, further comprising:
identifying an address associated with the request; and
routing the request to the non-volatile memory component based at least in part on the address associated with the request, wherein the address associated with the request is within a first portion of an address space for the volatile memory component, and wherein the one or more addresses are within a second portion of the address space for the volatile memory component.

19. The method of claim 17, further comprising:
identifying one or more mode registers based at least in part on the request, wherein the non-volatile memory component comprises the one or more mode registers.

20. An apparatus, comprising:
a volatile memory component; and
a non-volatile memory component configured to:
store information indicating one or more defective memory cells within the volatile memory component;
receive a request for an indication of the one or more defective memory cells within the volatile memory component; and
output, in response to the request, an indication of the one or more defective memory cells within the volatile memory component.

21. The apparatus of claim 20, wherein:
the apparatus comprises a memory module;
the volatile memory component comprises dynamic random access memory (DRAM) within the memory module; and
the non-volatile memory component comprises electrically erasable programmable read-only memory (EEPROM) within the memory module and configured to store serial presence detect (SPD) information for the DRAM that comprises the information indicating the one or more defective memory cells within the volatile memory component.

22. The apparatus of claim 20, wherein:
the apparatus comprises a plurality of dies within a package;
the volatile memory component comprises dynamic random access memory (DRAM) on a first die of the plurality of dies; and
the non-volatile memory component comprises NOT-AND (NAND) memory on a second die of the plurality of dies.

23. The apparatus of claim 20, wherein the apparatus comprises a die that comprises the volatile memory component and the non-volatile memory component.

24. The apparatus of claim 23, wherein the non-volatile memory component comprises one or more non-volatile mode registers.

25. The apparatus of claim 23, further comprising:
multiplexing circuitry configured to route commands for a first portion of an address space for the die to the volatile memory component and commands for a second portion of the address space for the die to the non-volatile memory component.
